(19) United States
(12) Patent Application Publication
(10) Pub. No.: US 2025/0089253 A1
(43) Pub. Date: Mar. 13, 2025

(54) SEMICONDUCTOR DEVICE AND MANUFACTURING METHOD

(71) Applicant: Kioxia Corporation, Tokyo (JP)

(72) Inventor: Ryusuke KON, Yokkaichi Mie (JP)

(21) Appl. No.: 18/882,666

(22) Filed: Sep. 11, 2024

(30) Foreign Application Priority Data
Sep. 12, 2023 (JP) 2023-147955

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80895; H01L 2224/80896; H01L 2924/1431; H01L 2924/14511

(57) ABSTRACT

According to an embodiment, a semiconductor device includes a lamination film of a plurality of first insulating films and a plurality of electrode layers alternately laminated on each other in a first direction. A plurality of contact plugs extend in the first direction. Each electrode layer in the lamination film contacts one of the contact plugs in a stair step region of the lamination film. Each contact plug contacts an uppermost electrode layer in a stair step portion of the stair step region. A center portion of a lower end of each contact plug has a concave shape.

### CROSS-REFERENCE TO RELATED APPLICATIONS

This application is based upon and claims the benefit of priority from Japanese Patent Application No. 2023-147955, filed Sep. 12, 2023, the entire contents of which are incorporated herein by reference.

### FIELD

Embodiments described herein relate generally to a semiconductor device and a manufacturing method thereof.

### BACKGROUND

When a stair structure portion including a plurality of electrode layers is formed and a contact plug is arranged to contact one of the electrode layers, there is a possibility that this contact plug short-circuits with another one of the electrode layers.

### BRIEF DESCRIPTION OF THE DRAWINGS

FIG. 1 is a cross-sectional view illustrating an example of a semiconductor device according to a first embodiment.

FIG. 2 is a plan view illustrating an example of the semiconductor device according to the first embodiment.

FIG. 3 is an enlarged cross-sectional view of a contact plug illustrating an example of the semiconductor device according to the first embodiment.

FIG. 4 is an enlarged cross-sectional view of a pillar-shaped portion illustrating an example of the semiconductor device according to the first embodiment.

FIGS. 5 to 13 depict aspects a manufacturing method of a semiconductor device according to a first embodiment.

FIGS. 14 to 17 depict aspects of a manufacturing method of a semiconductor device according to a comparative example.

FIG. 18 is a cross-sectional view illustrating a semiconductor device according to a second embodiment.

FIG. 19 is an enlarged cross-sectional view of a contact plug illustrating an example of the semiconductor device according to the second embodiment.

FIGS. 20 to 26 depict aspects of a manufacturing method of a semiconductor device according to a second embodiment.

FIG. 27 is a cross-sectional view illustrating a semiconductor device according to a third embodiment.

FIGS. 28 and 29 depict aspects of a manufacturing method of a semiconductor device according to a third embodiment.

### DETAILED DESCRIPTION

A semiconductor device in which a contact plug can be formed on an electrode layer and a manufacturing method for such a semiconductor device are described.

In general, according to one embodiment, semiconductor device has a first lamination film including a plurality of first insulating films and a plurality of electrode layers alternately laminated in a first direction. A plurality of contact plugs extend in the first direction. Each electrode layer in the first lamination film contacts a contact plug in the plurality of contact plugs in a stair step region of the first lamination film. Each contact plug contacts an uppermost electrode layer of the plurality of electrode layers in a stair step of stair step region. A center portion of a lower end of each contact plug has a concave shape.

Hereinafter, certain example embodiments will be described with reference to the drawings. In the drawings, the same reference symbols are given to the same aspects and an overlapping description may be omitted.

### First Embodiment

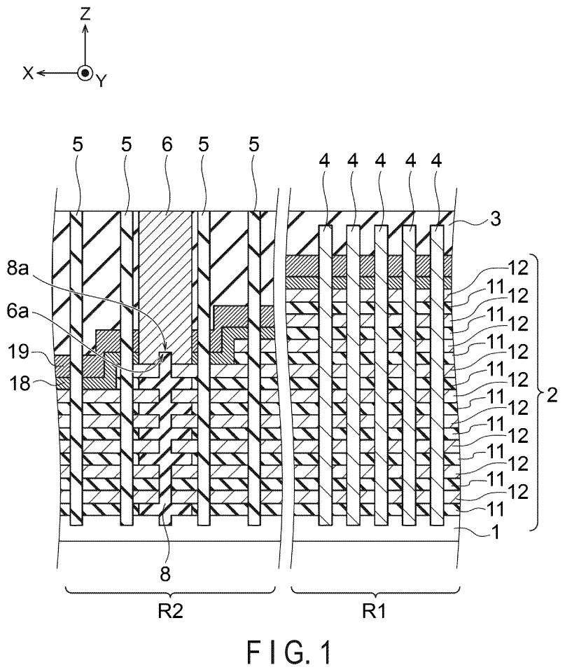

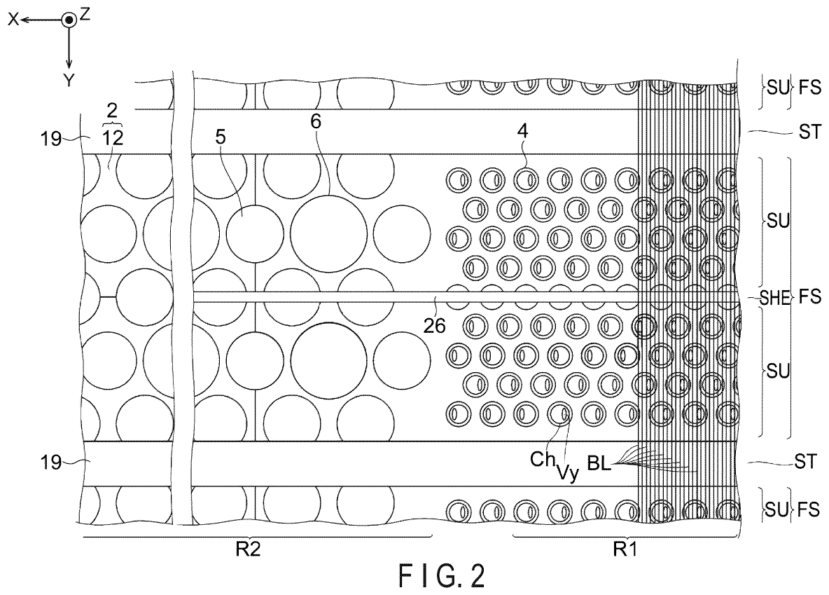

FIG. 1 is a cross-sectional view illustrating an example of a semiconductor device according to a first embodiment. FIG. 2 is a plan view illustrating an example of the semiconductor device according to the first embodiment. The semiconductor device according to the first embodiment can be a three-dimensional semiconductor memory, for example.

The semiconductor device according to the first embodiment includes a source layer 1, a lamination film 2, an insulating film 18, an insulating film 19, an interlayer insulation film 3, a plurality of pillar-shaped portions 4, a plurality of beam portions 5, a plurality of contact plugs 6, and a plurality of insulating films 8. The lamination film 2 includes a plurality of insulating films 11 and a plurality of electrode layers 12. The lamination film 2 is an example of a first lamination film. The interlayer insulation film 3 is an example of a seventh insulating film. The insulating film 18 is an example of a third insulating film. The insulating film 19 is an example of a second insulating film. The contact plug 6 is an example of a first plug. The insulating film 8 is an example of a fourth insulating film. The insulating film 11 is an example of a first insulating film.

For descriptive convenience, the drawings may illustrate an X direction, a Y direction, and a Z direction that are perpendicular to each other. In the description, a +Z direction may be referred to as an upper direction, and a −Z direction may be referred to as a lower direction. The −Z direction may coincide with the gravity direction or may not coincide with the gravity direction. The Z direction is an example of a first direction.

The semiconductor device may include a substrate under or above the source layer 1, the lamination film 2, and the interlayer insulation film 3. Alternatively, the semiconductor device may include two substrates under or above the source layer 1, the lamination film 2, and the interlayer insulation film 3.

In the first embodiment, the semiconductor device includes a substrate above the source layer 1, the lamination film 2, and the interlayer insulation film 3. A surface of the substrate is parallel to the X direction and the Y direction.

The source layer 1 is provided under the lamination film 2. The source layer 1 functions as a source line. The source layer 1 is, for example, a laminated film including a semiconductor layer and a metal layer. In FIG. 1, the source layer 1 extends in the X direction.

The lamination film 2 is provided between the source layer 1 and the interlayer insulation film 3. In FIG. 1, the lamination film 2 is provided on the source layer 1. The lamination film 2 comprises a plurality of insulating films 11 and a plurality of electrode layers 12 that are alternately laminated one on the other in the Z direction. Each insulating film 11 is, for example, a SiO₂ film (silicon oxide film). Each electrode layer 12 comprises, for example, a TiN film (titanium nitride film) as a barrier metal layer. Each electrode layer 12 may further comprise a W (tungsten) layer as an electrode material layer. Each electrode layer 12 functions as, for example, a word line or a selection line.

The lamination film 2 includes a flat portion R1 having a flat/planar upper surface and a stair structure portion R2 having a stair-like upper surface. The stair structure portion R2 includes a plurality of portions corresponding to respective steps of stairs, which are also called terrace portions.

The insulating film 18 is provided on the upper surface of the lamination film 2. The insulating film 18 is provided on the lamination film 2 so as to cover the side walls of the insulating films 11 and the electrode layers 12 within the stair structure portion R2. The insulating film 18 is penetrated by the contact plug 6 in the stair structure portion R2. The insulating film 18 is also penetrated by the pillar-shaped portions 4 (pillars 4) and the beam portions 5 (beams 5). The insulating film 18 is, for example, a SiO₂ film (silicon oxide film).

The insulating film 19 is provided on the lamination film 2 via the insulating film 18. The insulating film 18 has a smaller thickness in the Z direction than the insulating film 19. The insulating film 19 is provided over the insulating film 18. The insulating film 19 is penetrated by the contact plug 6. The insulating film 19 is also penetrated by the pillar-shaped portions 4 and the beam portions 5. The insulating film 19 has a greater thickness in the Z direction than the individual insulating films 11 and electrode layers 12. The insulating film 19 is, for example, a SiO₂ film.

The interlayer insulation film 3 is provided on the lamination film 2. In FIG. 1, the interlayer insulation film 3 is provided on the lamination film 2 via the insulating film 18 and the insulating film 19. That is, the interlayer insulation film 3 is provided above the lamination film 2. Further, in other words, the interlayer insulation film 3 is provided on the insulating film 19. Additionally, in FIG. 1, the interlayer insulation film 3 covers upper surfaces and side surfaces of the flat portion R1 and the stair structure portion R2. The interlayer insulation film 3 is, for example, a SiO₂ film.

The plurality of pillar-shaped portions 4 are provided in the flat portion R1. Each pillar-shaped portion 4 penetrates the lamination film 2 in the Z direction. Each pillar-shaped portion 4 has a pillar shape extending lengthwise in the Z direction. Each pillar-shaped portion 4 forms a plurality of cell transistor (memory cells) and a plurality of selection transistors (selection gates), together with the plurality of electrode layers 12.

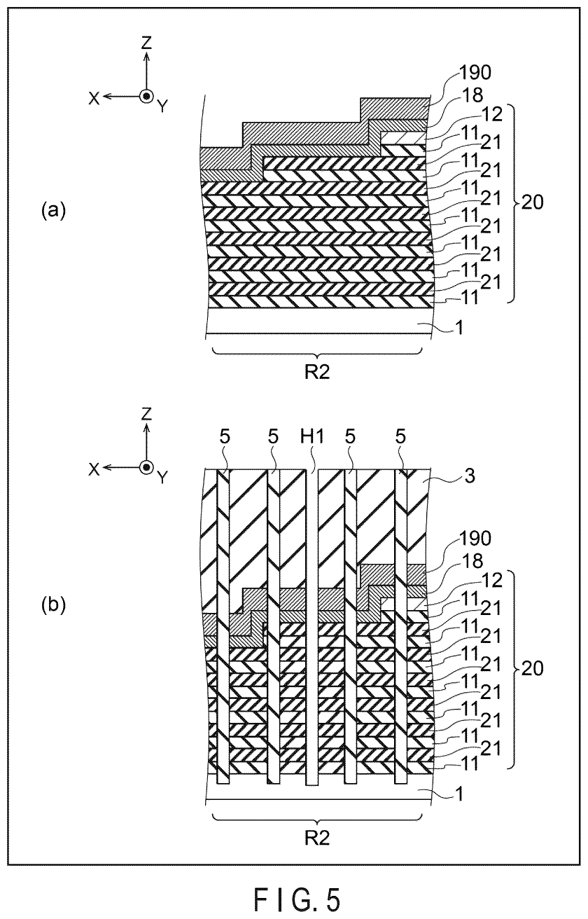

The plurality of beam portions 5 are provided in the stair structure portion R2. Each beam portion 5 penetrates the lamination film 2 in the Z direction. Each beam portion 5 has a pillar shape extending lengthwise in the Z direction. Each beam portion 5 functions as a structural support (e.g., a structural support beam) for preventing lamination film 20 from collapsing during the processing for replacement of sacrificial layers 21 (refer to FIG. 5). Each beam portion 5 may have the same or the different length in the Z direction as the pillar-shaped portions 4. Each beam portion 5 is formed of, for example, an insulating material such as a SiO₂ film.

n FIG. 1, each beam portion 5 penetrates all the insulating films 11 and electrode layers 12 in the stair structure portion R2 at the step to which the beam portion 5 is provided, so as to reach the source layer.

The contact plugs 6 are provided on the stair structure portion R2 through the interlayer insulation film 3. Each contact plug 6 has a pillar shape extending lengthwise in the Z direction. Each contact plug 6 comprises, for example, a TiN film as a barrier metal layer. Each contact plug 6 comprises, for example, a W layer as an inner plug material layer. The shape of an XY cross-section of the contact plug 6 is, for example, a circle. Although it is usually desirable that the circle is a perfect circle, the shape may be distorted from a perfect circle or may be another shape. In FIG. 1, the beam portions 5 and the contact plug 6 are separated from each other in the X direction.

Each contact plug 6 is arranged on an uppermost exposed electrode layer 12 in the plurality of electrode layers 12 of the lamination film 2 in the stair structure portion R2. The respective contact plug 6 is electrically connected to the uppermost exposed electrode layer 12. That is, each contact plug 6 is arranged on an uppermost electrode layer 12 in the stair structure portion R2. The uppermost exposed electrode layer 12 may be referred to as a first electrode layer. Each contact plug 6 electrically connects the uppermost electrode layer 12 to a transistor or the like.

In some examples, the lower end of the contact plug 6 may be located inside but above the bottom surface of the uppermost electrode layer 12 to which it is connected.

The contact plug 6 may have a bowed or non-constant outer shape that has its largest diameter at an intermediate position between an upper end portion and a bottom end portion of the contact plug 6. In the stair structure portion R2, the position of the largest diameter of the corresponding contact plug 6 may be closer to an upper step portion than a lower step portion.

As illustrated in FIG. 2, slits ST and a groove SHE are provided in the semiconductor device according to the first embodiment. The plurality of slits ST are arranged at intervals in the Y direction, and extend in the X direction. The groove SHE is arranged between two slits ST that are otherwise adjacent to each other in the Y direction, and extends in the X direction. The slit ST penetrates the lamination film 2. The slit ST is filled with the insulating film 19. The groove SHE penetrates one or more electrode layers 12 that function as a drain side selection line for a plurality of electrode layers 12 included in the lamination film 2. The groove SHE is filled with the insulating film 26.

The area between the two adjacent slits ST corresponds to one finger structure FS in one block of a three-dimensional semiconductor memory. The finger structure FS includes a plurality of string units SU that are adjacent to each other in the Y direction. The groove SHE is provided between the plurality of string units SU. The semiconductor device according to the first embodiment further includes contact plugs Ch and Vy provided on each of the pillar-shaped portions 4, and a plurality of bit lines BL extending in the Y direction.

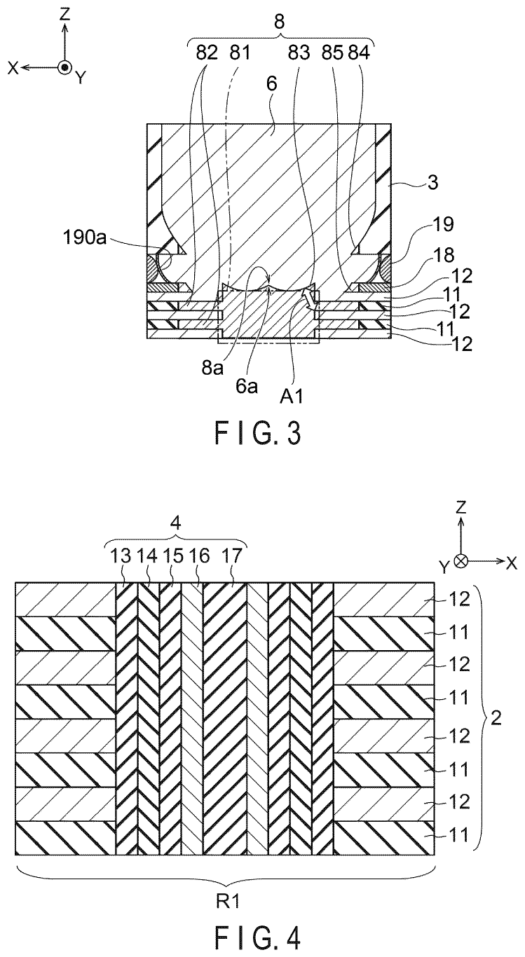

FIG. 3 is an enlarged cross-sectional view of a contact plug illustrating an example of the semiconductor device according to the first embodiment. Note that FIG. 3 illustrates one contact plug 6 as a representative of the plurality of contact plugs 6. As illustrated in FIG. 3, a center portion 6a of the lower end of each contact plug 6 has a concave shape that is recessed upward. In FIG. 3, an arc-shaped convex shape of the lower end of the contact plug 6 is formed around the concave shape of the center portion 6a of the lower end of the contact plug 6. Since the center portion 6a of the lower end of each contact plug 6 has a concave shape, it is possible to increase an interval A1 between the lower end of each contact plug 6 and the electrode layer 12 (that is, a word line) that is lower than the uppermost electrode layer 12.

The plurality of insulating films 8 are provided in the stair structure portion R2 so as to penetrate the lamination film 2. Each insulating film 8 is arranged under the corresponding contact plug 6. Each insulating film 8 has a pillar shape generally extending in the Z direction. Each insulating film 8 is, for example, a silicon oxide film. More specifically, each insulating film 8 may be an LP-TEOS (Low-Pressure Tetra-ethoxysilane) film or an ALD (Atomic Layer Deposition) SiO₂ film. By adopting an LP gas-TEOS film as the insulating film 8, the manufacturing throughput may be improved. By adopting an ALD SiO₂ film as the insulating film 8, when forming a rib-like portion such as a fifth portion 85, the rib-like portion can be filled with the insulating film 8 with fewer gaps.

A center portion 8a of an upper end of each insulating film 8 located under the center portion 6a of the lower end of the corresponding contact plug 6 has a convex shape to match the concave shape of the center portion 6a of the lower end of the corresponding contact plug 6.

The height (that is, the dimension in the Z direction) for the convex shape of the center portion 8a may be greater than an upper step side portions of the contact plug 6 near the outer diameter of the bowed shape of the contact plug 6.

In FIG. 3, the insulating film 8 includes a first portion 81, a plurality of second portions 82, a third portion 83, a fourth portion 84, and a fifth portion 85.

The first portion 81 penetrates the lamination film 2. The plurality of second portions 82 are arranged on an outer side of the first portion 81. The second portions 82 are adjacent to the side walls of the plurality of insulating films 11 of the lamination film 2, respectively. The second portions 82 are arranged on corresponding electrode layers 12.

The third portion 83 is arranged on the first portion 81. In FIG. 3, an upper end of the third portion 83 is approximately at the same height as the center portion 8a. Accordingly, in FIG. 3, the convex shape of the center portion 8a is in conjunction with the upper end of the third portion 83. Note that, depending on the etching rate of the insulating film 8, the third portion 83 may not remain on the first portion 81 after processing. In this case, the convex shape of the upper end of the insulating film 8 is formed in conjunction with the upper end of the first portion 81. The fourth portion 84 is arranged above the plurality of second portions 82. The fifth portion 85 is arranged adjacent to the insulating film 18.

FIG. 4 is an enlarged cross-sectional view of the pillar-shaped portion 4 illustrating an example of the semiconductor device according to the first embodiment. As illustrated in FIG. 4, each pillar-shaped portion 4 includes a block insulating film 13, a charge accumulation layer 14, a tunnel insulating film 15, a channel semiconductor layer 16, and a core insulating film 17 that are sequentially provided in the flat portion R1.

The block insulating film 13, the charge accumulation layer 14, the tunnel insulating film 15, and the channel semiconductor layer 16 have tubular shapes extending in the Z direction. The core insulating film 17 has a pillar shape extending in the Z direction. The block insulating film 13 is, for example, a SiO₂ film. The charge accumulation layer 14 is, for example, an insulating film such as a SiN film (silicon nitride film) or a semiconductor layer such as a polysilicon layer. The charge accumulation layer 14 can accumulate the data signal charge of each memory cell. The tunnel insulating film 15 is, for example, a SiO₂ film. The channel semiconductor layer 16 is, for example, a polysilicon layer. The channel semiconductor layer 16 is electrically connected between the source layer 1 (refer to FIG. 1) and a bit line. The core insulating film 17 is, for example, a SiO₂ film.

Next, a manufacturing method of the semiconductor device according to the first embodiment will be described. First, the source layer 1 is formed, and the lamination film 20, the insulating film 18, and a sacrificial layer 190 are then formed on the source layer 1 (FIG. 5, part (a)). The lamination film 20 is an example of a second lamination film. The lamination film 20 is formed on the source layer 1 by alternately laminating insulating films 11 and sacrificial layers 21. The sacrificial layer 21 is an example of a first film. The sacrificial layer 190 is an example of a second film. The sacrificial layers 21 and 190 are, for example, SiN films (that is, silicon nitride films). Similar to the lamination film 2 illustrated in FIG. 1, the lamination film 20 is processed to include the flat portion R1 and the stair structure portion R2. The specific illustration of the flat portion R1 is omitted in FIG. 5, part (a).

After forming the sacrificial layer 190, the interlayer insulation film 3 is formed on the sacrificial layer 190. After forming the interlayer insulation film 3, a plurality of contact holes H1 are formed by lithography and RIE (Reactive Ion Etching) in the interlayer insulation film 3, the sacrificial layer 190, the insulating film 18, and the lamination film 20 (FIG. 5, part (b)). The contact hole H1 is an example of a first concave portion. Each contact hole H1 is formed to reach the source layer 1. When forming each contact hole H1, holes for the beam portions 5 may also be formed by lithography and RIE in the interlayer insulation film 3, the sacrificial layer 190, the insulating film 18, and the lamination film 20.

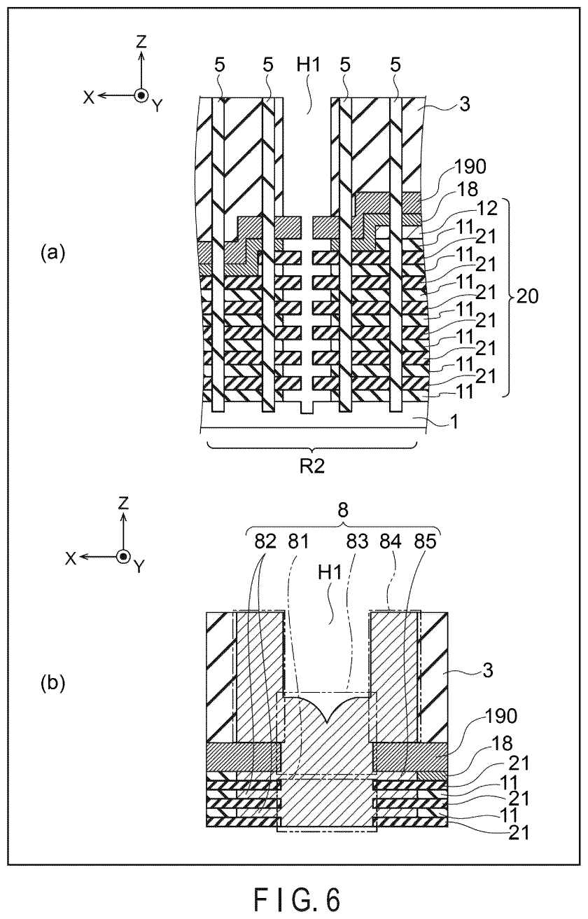

After forming each contact hole H1, the side walls of the insulating films 11 and 18 and the interlayer insulation film 3 are recessed relative to the side walls of the sacrificial layers 21 and 190 in each contact hole H1 by wet etching using a chemical solution (FIG. 6, part (a)). The diameter of the contact plug 6 can be increased by retreating (recessing) the side walls of the interlayer insulation film 3. The wet etching can be performed such that the side surface of each contact hole H1 does not reach the side surfaces of the holes for the beam portions 5.

After retreating the side walls of the insulating films 11 and 18 and the interlayer insulation film 3 relative to the side walls of the sacrificial layers 21 and 190, the insulating film 8 is formed on the lamination film 20, the insulating film 18, the sacrificial layer 190, and the interlayer insulation film 3 (FIG. 6, part (b)). As a result, an insulating film 8 is formed in each contact hole H1 so as to include the first portion 81, the second portions 82, the third portion 83, the fourth portion 84, and the fifth portion 85 (FIG. 6, part (b)).

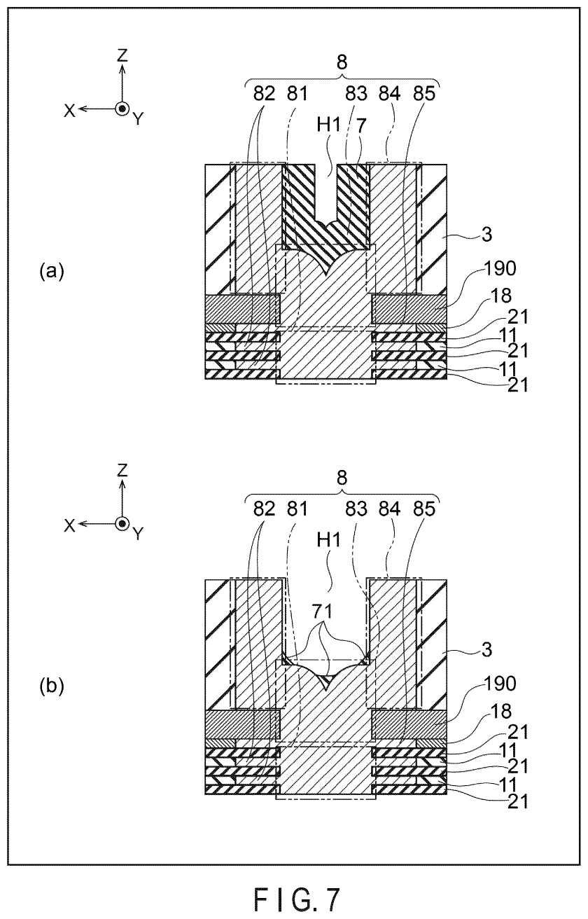

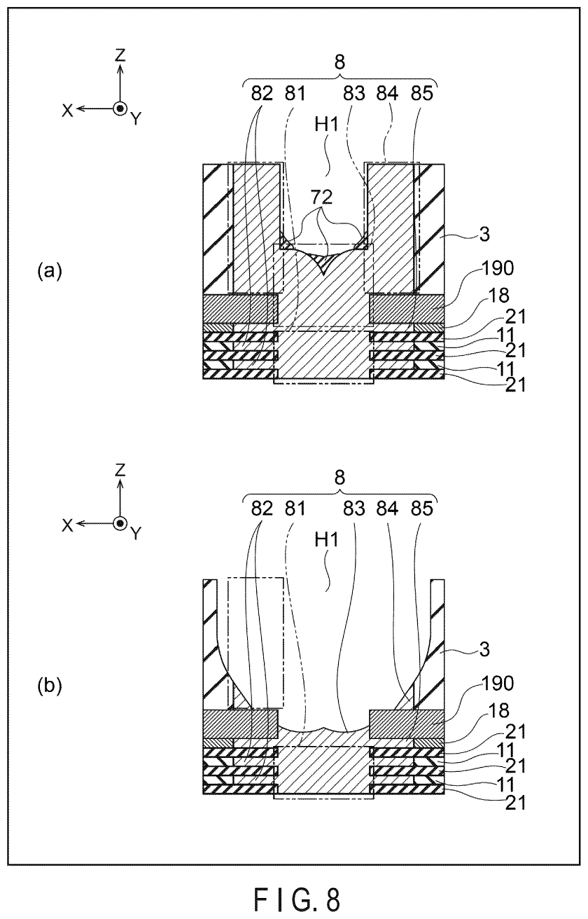

After forming the insulating film 8, the insulating film 8 is processed such that at least the etching rate of the center portion of the third portion 83 is less than the etching rate of the fourth portion 84. Specifically, an insulating film 7 can be formed on the third portion 83 and the fourth portion 84 (FIG. 7, part (a)). The insulating film 7 is an example of a sixth insulating film. The insulating film 7 is, for example, an amorphous silicon film. After forming the insulating film 7, the insulating film 7 is removed by wet etching using a chemical solution, leaving a bottom end portion 71 of the insulating film 7 that contacts the third portion 83 (FIG. 7, part (b)). After removing the insulating film 7 leaving the bottom end portion 71 of the insulating film 7, the bottom end portion 71 is then thermally oxidized to form a thermal oxide film 72 (FIG. 8, part (a)). The thermal oxide film 72 is an example of the bottom end portion 71 after the thermal oxidizing of the insulating film 7. In this manner, the insulating film 8 is processed such that at least the etching rate of the center portion of the third portion 83 becomes less than the etching rate of the fourth portion 84. That is, at least the etching selection ratio of the center portion of the third portion 83 becomes less than the etching selection ratio of the fourth portion 84.

Then, the third portion 83 and the fourth portion 84 are partially removed by wet etching using a chemical solution. The chemical solution includes, for example, hydrofluoric acid. When partially removing the third portion 83 and the fourth portion 84, the thermal oxide film 72 on the third portion 83 is entirely removed (FIG. 8, part (b)). Since the etching rate of the third portion 83 is less than the etching rate of the fourth portion 84 (due to the thermal oxide film 72) more of the third portion 83 than the fourth portion 84 remains after the wet etching. Accordingly, the center portion 8a of the upper end of the third portion 83, which is the center portion 8a of the upper end of the insulating film 8, has a convex shape. Note that the third portion 83 may be entirely removed by wet etching. In this case, the center portion 8a of the upper end of the first portion 81, which is the center portion 8a of the upper end of the insulating film 8, is formed into a convex shape.

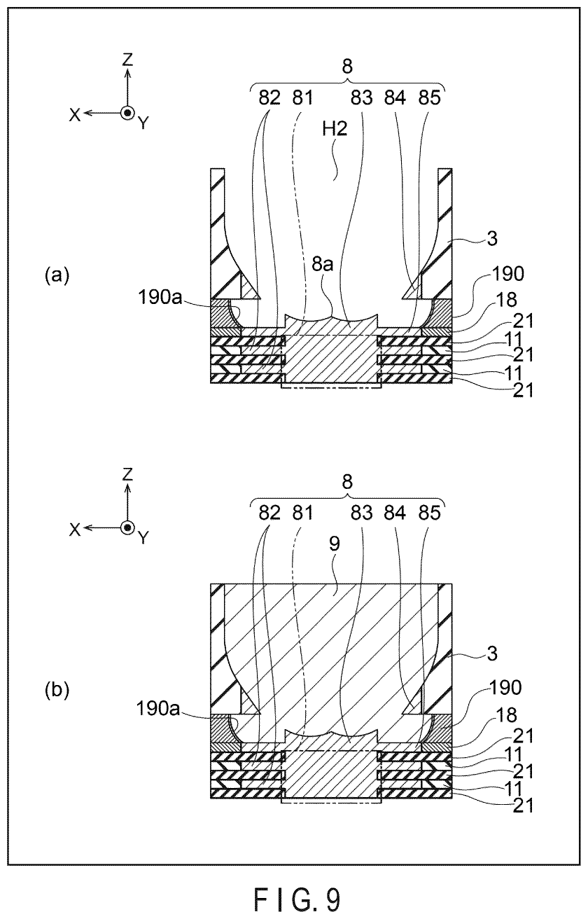

After partially removing the third portion 83 and the fourth portion 84, a side wall 190a of the sacrificial layer 190 is recessed relative to the side walls of the sacrificial layers 21 by the wet etching using a chemical solution (FIG. 9, part (a)). After recessing the side wall 190a of the sacrificial layer 190 with respect to the side walls of the sacrificial layers 21, the retreated side wall 190a of the sacrificial layer 190 is oxidized. The side wall 190a of the sacrificial layer 190 can be oxidized by, for example, PIO (Plasma-Induced Oxidation) using plasma. Accordingly, a concave portion H2 is formed on the first portion 81 and above the second portion 82 (FIG. 9, part (a)). The concave portion H2 is an example of a second concave portion. Since the center portion 8a of the upper end of the third portion 83 has the convex shape, a center portion of a bottom surface of the concave portion H2 has a convex shape.

After oxidizing the side wall 190a of the sacrificial layer 190, an insulating film 9 is formed in the concave portion H2 (FIG. 9, part (b)). The insulating film 9 is an example of an eighth insulating film. The insulating film 9 is, for example, an amorphous silicon film.

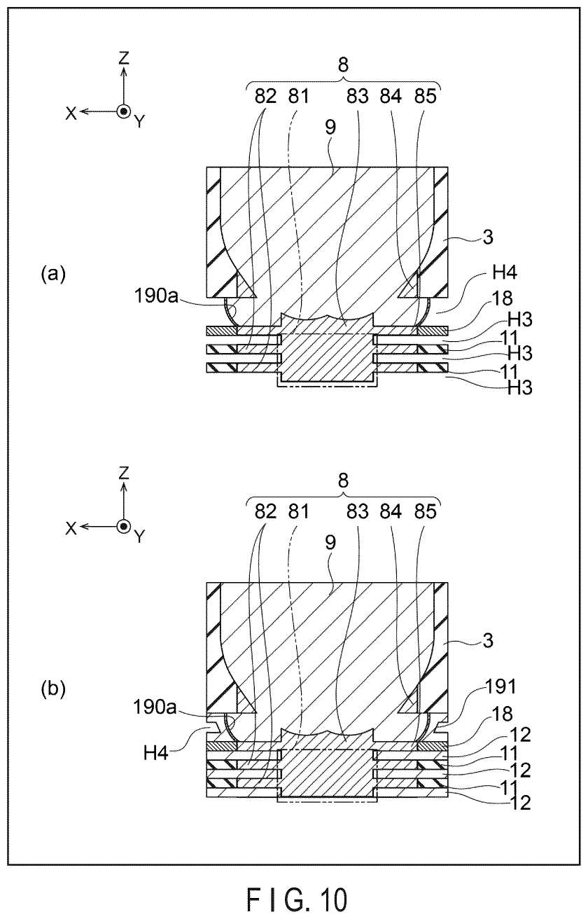

After forming the insulating film 9, a concave portion H4 is formed by removing the sacrificial layer 190 by wet etching using a chemical solution, leaving the oxidized side wall 190a of the sacrifice layer 190 (FIG. 10, part (a)). The concave portion H4 is an example of a fourth concave portion. The sacrificial layers 21 are then removed to form concave portions H3 by wet etching using a chemical solution (FIG. 10, part (a)). The chemical solution contains, for example, phosphoric acid.

After forming the concave portions H3 and H4, the electrode layers 12 are formed in the concave portions H3, and a conductive layer 191 is formed in the concave portion H4 (FIG. 10, part (b)). The conductive layers can also be formed in the slits ST at this time. Since the electrode layers 12 are formed in the concave portions H3, the sacrificial layers 21 of the lamination film 20 are replaced with the electrode layers 12.

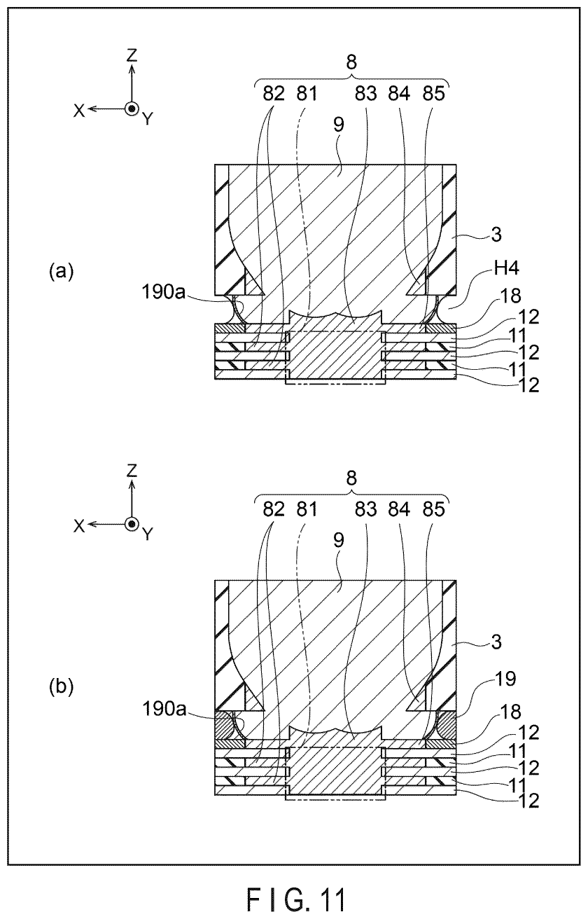

After forming the electrode layers 12 and the conductive layer 191, the conductive layer 191 in the concave portion H4 is removed together with the conductive layers in the slits ST by wet etching using a chemical solution (FIG. 11, part (a)).

After removing the conductive layer 191 in the concave portion H4, the insulating film 19 is formed in the concave portion H4 and the slits ST (FIG. 11, part (b)).

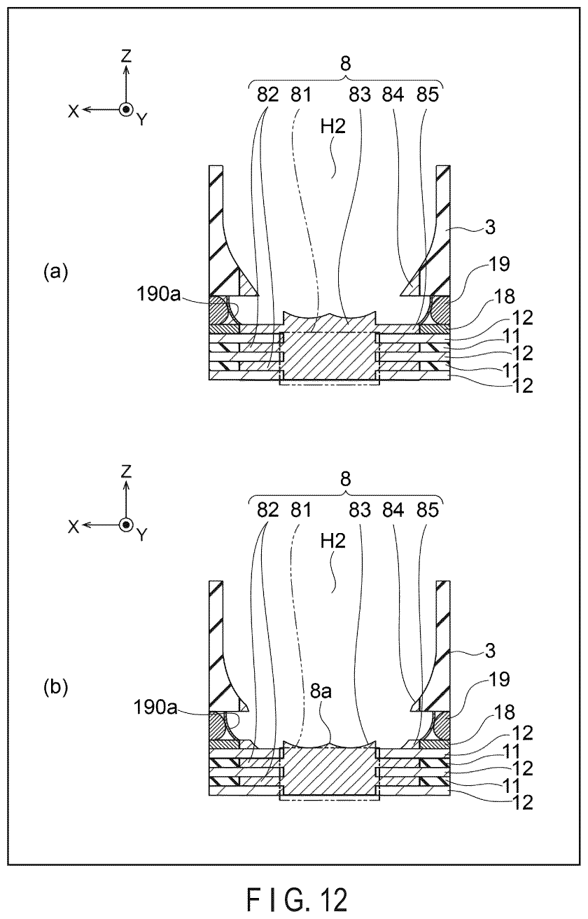

After forming the insulating film 19, the insulating film 9 in the concave portion H2 is removed by wet etching using a chemical solution (FIG. 12, part (a)).

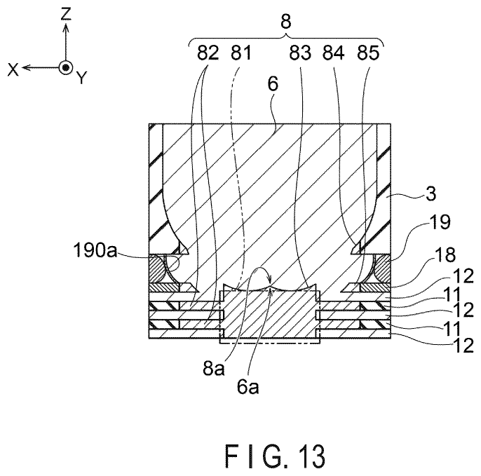

After removing the insulating film 9 in the concave portion H2, the uppermost electrode layer 12 (that is, the connection word line) is exposed by removing most of the fifth portion 85 by etching (FIG. 12, part (b)). After exposing the uppermost electrode layer 12, the contact plug 6 is formed in the concave portion H2 (FIG. 13). Since the center portion of the bottom surface of the concave portion H2 (that is, the center portion 8a of the upper end of the insulating film 8) has the convex shape, the center portion 6a of the lower end of the contact plug 6 has the concave shape. Since the center portion 6a of the lower end of the contact plug 6 has the concave shape, it is possible to increase the interval A1 (refer to FIG. 3) between the lower end of the contact plug 6 and the electrode layer 12 under the uppermost electrode layer 12. By increasing the interval A1 between the lower end of the contact plug 6 and the electrode layer 12 under the uppermost electrode layer 12, the voltage resistance between the contact plug 6 and an unconnected word line (a word line to which the contact plug 6 is not intended to be connected) can be improved. By improving the voltage resistance, short-circuits between the contact plug 6 and the unconnected word line can be reduced.

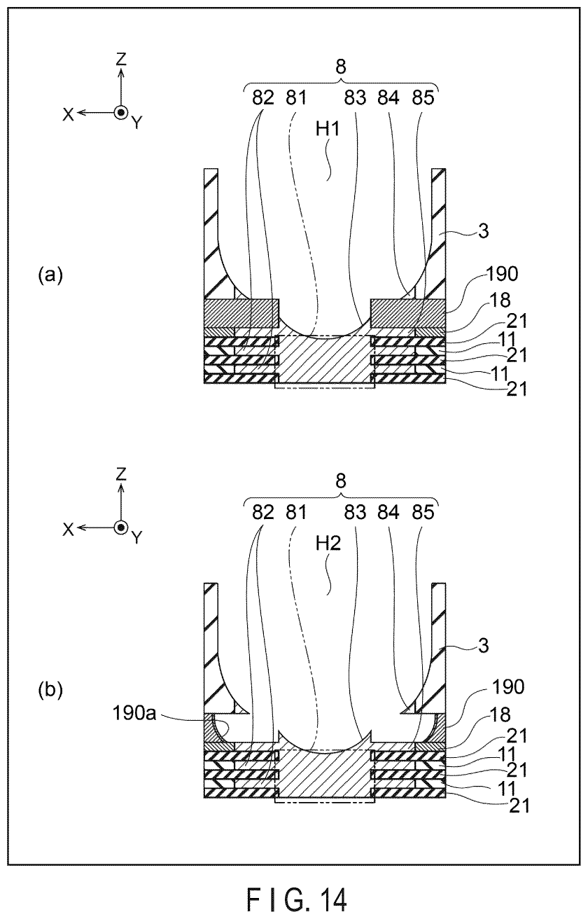

Next, a manufacturing method of a semiconductor device according to a comparative example of the first embodiment will be described. In the comparative example, after forming the insulating film 8 in the contact hole H1, without forming the thermal oxide film 72 (refer to FIG. 8, part (a)), the third portion 83 and the fourth portion 84 are partially removed by wet etching using a chemical solution (FIG. 14, part (a)). Since the etching rate of the third portion 83 is not reduced by the thermal oxide film 72, an upper end portion of the third portion 83 after the wet etching has a concave shape.

After partially removing the third portion 83 and the fourth portion 84, the side wall 190a of the sacrificial layer 190 is recessed relative to the side walls of the sacrificial layers 21 by wet etching using a chemical solution (FIG. 14, part (b)). After recessing the side wall 190a of the sacrificial layer 190 relative to the side walls of the sacrificial layers 21, the recessed side wall 190a is oxidized. Accordingly, the concave portion H2 of the insulating film 8 is formed (FIG. 14, part (b)). Since the upper end portion of the third portion 83 has a concave shape, a center portion of a bottom surface of the concave portion H2 has a concave shape.

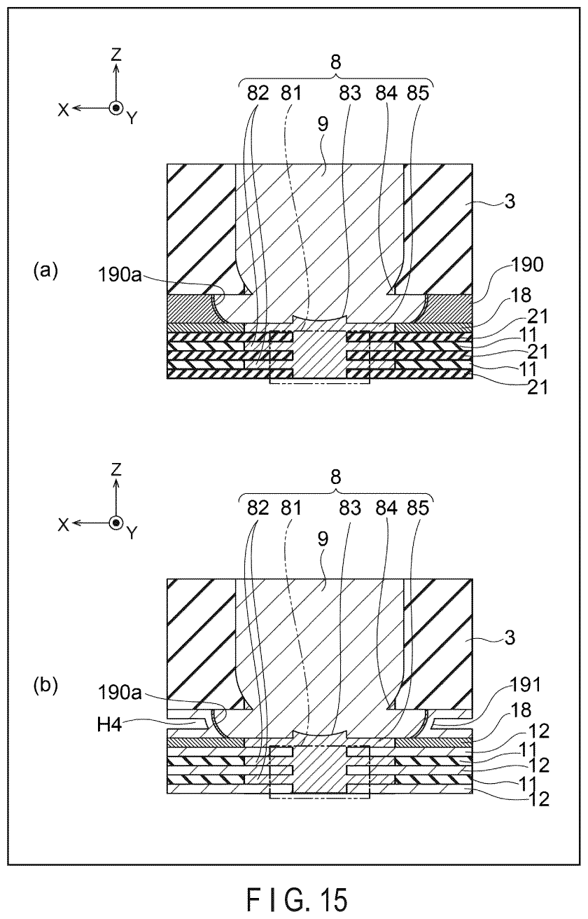

After oxidizing the side wall 190a of the sacrificial layer 190, the insulating film 9 is formed in the concave portion H2 (FIG. 15, part (a)).

After forming the insulating film 9, the concave portion H4 is formed by removing the sacrificial layer 190 by wet etching using a chemical solution, leaving the oxidized side wall 190a of the sacrificial layer 190. The concave portions H3 are then formed by removing the sacrificial layers 21 by wet etching using a chemical solution (refer to FIG. 10, part (a)). After forming the concave portions H3 and H4, the electrode layers 12 are formed in the concave portions H3, and the conductive layer 191 is formed in the concave portion H4 (FIG. 15, part (b)). The conductive layers can also be formed in the slits ST at this time. After the electrode layers 12 are formed in the concave portions H3, the sacrificial layers 21 of the lamination film 20 can be said to have been replaced with the electrode layers 12.

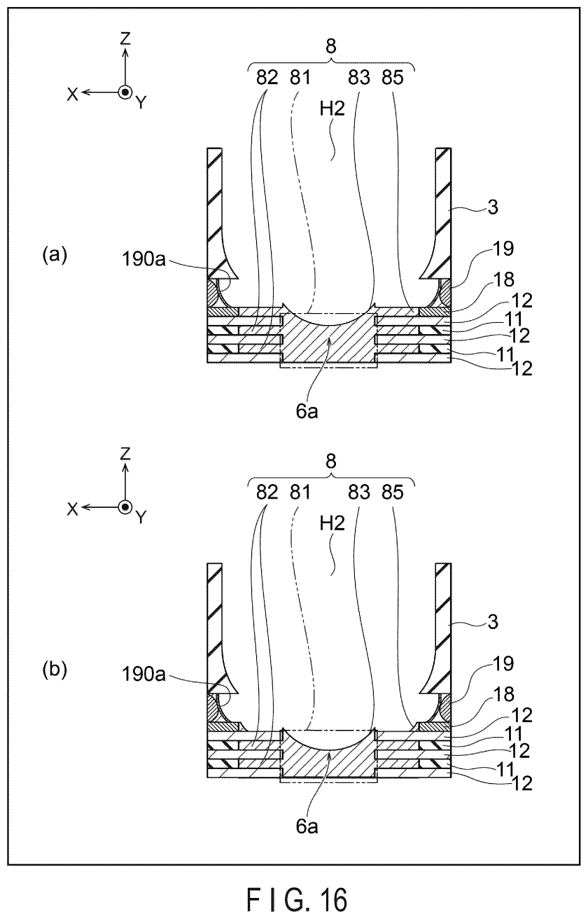

After forming the electrode layers 12 and the conductive layer 191, the conductive layer 191 in the concave portion H4 is removed together with the conductive layers in the slits ST by wet etching using a chemical solution (refer to FIG. 11, part (a)). After removing the conductive layer 191 in the concave portion H4, the insulating film 19 is formed in the concave portion H4 and the slits ST (FIG. 16, part (a)). After forming the insulating film 19, the insulating film 9 in the concave portion H2 is removed by wet etching using a chemical solution (FIG. 16, part (a)).

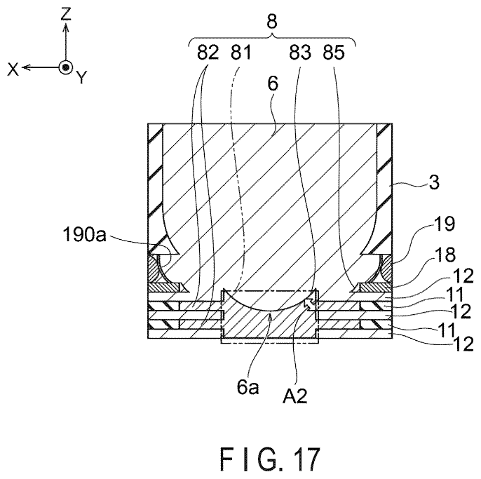

After removing the insulating film 9 in the concave portion H2, the uppermost electrode layer 12 is exposed by removing most of the fifth portion 85 by etching (FIG. 16, part (b)). After exposing the uppermost electrode layer 12, the contact plug 6 is formed in the concave portion H2 (FIG. 17). Since the center portion of the bottom surface of the concave portion H2 has the concave shape, the center portion 6a of the lower end of the contact plug 6 has a convex shape. Since the center portion 6a of the lower end of the contact plug 6 has the convex shape, an interval A2 between the lower end of the contact plug 6 and the electrode layer 12 under the uppermost electrode layer 12 cannot be increased. Accordingly, in the semiconductor device according to the comparative example, the voltage resistance between the contact plug 6 and an unconnected word line cannot be improved.

As described above, in the first embodiment, the center portion 6a of the lower end of the contact plug 6 provided on the uppermost electrode layer 12 has the concave shape.

Accordingly, since the interval A1 between the lower end of the contact plug 6 and the electrode layer 12 under the uppermost electrode layer 12 can be increased, the voltage resistance between the contact plug 6 and an unconnected word line (a word line to which the contact plug 6 is not intended to be connected) can be improved. As a result, it becomes possible to form the contact plugs 6 on the electrode layers 12 in an improved manner.

Additionally, in the first embodiment, the insulating film 19 that is penetrated by the contact plug 6 has a larger thickness in the Z direction than the insulating films 11 and the electrode layers 12 on the lamination film 2.

Accordingly, since the interval A1 between the lower end of the contact plug 6 and the next electrode layer 12 under the uppermost electrode layer 12 (the electrode layer 12 to which the contact plug 6 is electrically connecting) can be further increased, the voltage resistance between the contact plug 6 and an unconnected word line (a word line or electrode layer 12 to which the contact plug 6 is not intended to be connected) can be further improved.

Additionally, in the first embodiment, the insulating film 19 is provided on the lamination film 2 via an insulating film 18 that has a smaller thickness in the Z direction than the insulating film 19.

Accordingly, since the interval A1 between the lower end of the contact plug 6 and the next electrode layer 12 under the uppermost electrode layer 12 can be further increased, the voltage resistance between the contact plug 6 and a word line to which the contact plug 6 is not intended to be electrically connected can be further improved.

Additionally, in the first embodiment, the insulating film 8 penetrating the lamination film 2 and located under the contact plug 6 is provided in the lamination film 2.

Accordingly, since the holes for the beam portions 5 and the contact hole H1 for a contact plug 6 can be formed at the same time, the manufacturing efficiency can be improved.

Additionally, in the first embodiment, the center portion 8a of the upper end of the insulating film 8 located under the center portion 6a of the lower end of the contact plug 6 has a convex shape.

Accordingly, the center portion 6a of the lower end of the contact plug 6 can be formed into a concave shape by a simple method.

Additionally, in the first embodiment, the insulating film 8 is processed such that at least the etching rate of the center portion of the third portion 83 becomes less than the etching rate of the fourth portion 84.

Accordingly, the center portion 8a of the upper end of the insulating film 8 can be formed into a convex shape by a simple method.

Additionally, in the first embodiment, the insulating film 7 is formed on the third portion 83 and the fourth portion 84. The insulating film 7 is then substantially removed leaving just the bottom end portion 71 of the insulating film 7. The bottom end portion 71 of the insulating film 7 can then be thermally oxidized. The formation of the concave portion H2 includes removing the bottom end portion 71 of the thermally oxidized insulating film 7 when removing the third portion 83 and the fourth portion 84 or parts thereof.

Accordingly, since the etching rate of the third portion 83 can be reduced, the center portion 8a of the upper end of the insulating film 8 can be appropriately formed into the convex shape.

Additionally, in the first embodiment, the formation of the concave portion H2 further includes recessing the side wall 190a of the sacrificial layer 190 relative to the side wall of the sacrificial layer 21 after at least partially removing the third portion 83 and the fourth portion 84, and then oxidizing the recessed side wall 190a of the sacrificial layer 190. In the first embodiment, after the side wall 190a of the sacrificial layer 190 is oxidized, the insulating film 9 is formed in the concave portion H2. After the insulating film 9 is formed, the sacrificial layer 190 is removed leaving the oxidized side wall 190a of the sacrificial layer 190, and the concave portion H4 is formed. Additionally, the insulating film 19 is formed in the concave portion H4.

Accordingly, the insulating film 19 above the lamination film 2 can be appropriately formed.

### Second Embodiment

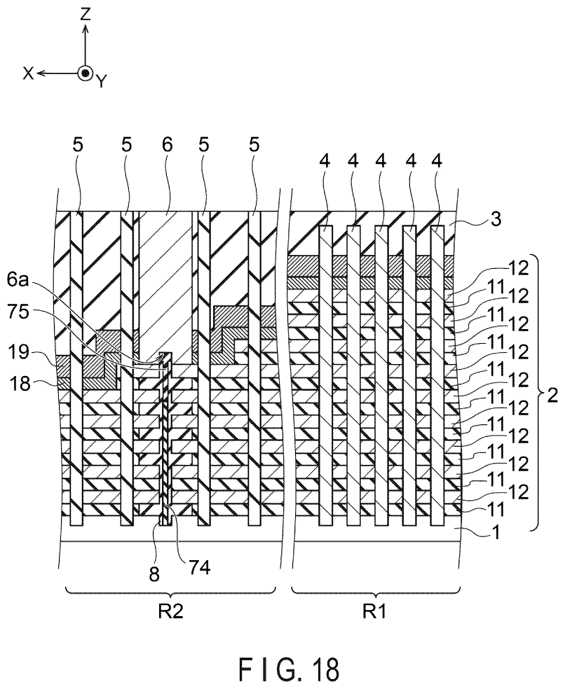

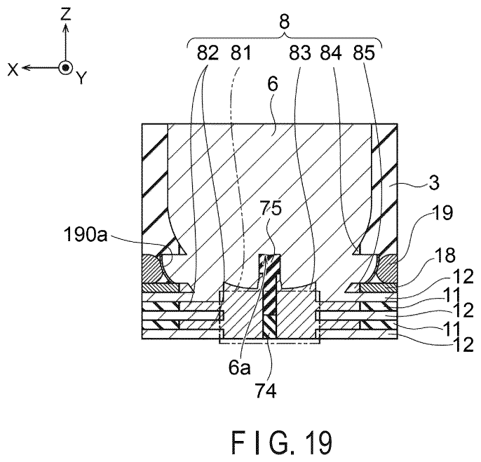

Next, a semiconductor device according to a second embodiment will be described by focusing on the differences from the first embodiment. FIG. 18 is a cross-sectional view illustrating the semiconductor device according to the second embodiment. FIG. 19 is an enlarged cross-sectional view of the contact plug 6 illustrating an example of the semiconductor device according to the second embodiment.

As illustrated in FIG. 18 and FIG. 19, the semiconductor device according to the second embodiment further includes an insulating film 74 and an insulating film 75 in addition to the configuration of the first embodiment. The insulating film 74 is an example of a sixth insulating film. The insulating film 75 is an example of a fifth insulating film.

The insulating film 75 is provided in the insulating film 8. The insulating film 75 is provided in a center portion of the insulating film 8. The insulating film 75 is located under the center portion 6a of the lower end of the contact plug 6. The insulating film 75 extends lengthwise in the Z direction and has a pillar shape that is thinner (narrower) than the first portion 81. An upper end portion of the insulating film 75 has a convex shape along the concave shape of the center portion 6a of the lower end of the contact plug 6. That is, in the second embodiment, since the upper end portion of the insulating film 75 constituting the center portion of the bottom surface of the concave portion H2 has a convex shape, the center portion 6a of the lower end of the contact plug 6 on the upper end portion of the insulating film 75 has a concave shape. The insulating film 75 is, for example, a silicon oxide film. The insulating film 75 may be a SiCN film.

The insulating film 74 is provided in the insulating film 8. The insulating film 74 is located under the insulating film 75 in the center portion of the insulating film 8. The insulating film 74 has a pillar shape extending lengthwise in the Z direction. The outer diameter of the insulating film 74 may be the same as the outer diameter of the insulating film 75. The insulating film 74 is, for example, an amorphous silicon material.

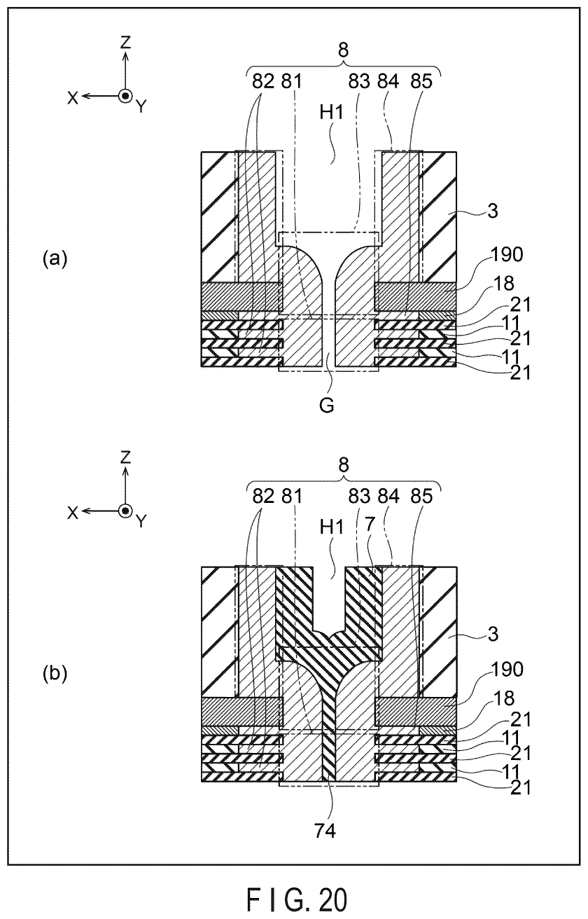

Next, a manufacturing method of the semiconductor device according to the second embodiment will be described. In the second embodiment, the insulating film 8 is formed in the contact hole H1 so as to leave a gap G in the center portion of the first portion 81 and the center portion of the third portion 83 (FIG. 20, part (a)).

After forming the insulating film 8 so as to leave the gap G, the insulating film 7 is formed on the insulating film 8 with a core portion 74 that fills the gap G (FIG. 20, part (b)). Note that, when the insulating film 75 illustrated in FIG. 19 is formed by a SiCN film, instead of forming the insulating film 74 (an amorphous silicon film), the insulating film 75 (SiCN film) may be formed so as to fill the gap G itself.

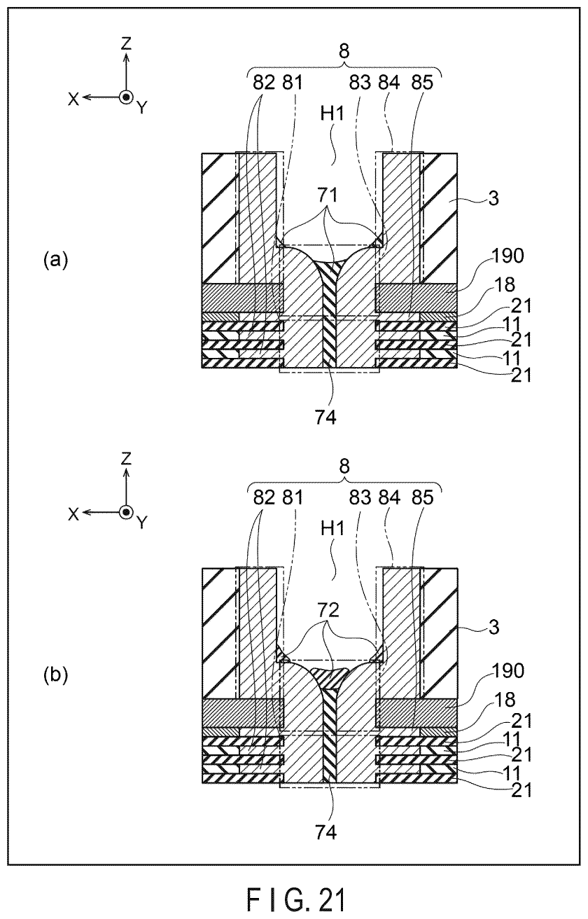

After forming the insulating film 7 with a core portion 74, portions of the insulating film 7 are removed by wet etching using a chemical solution, leaving the bottom end portion 71 of the insulating film 7 contacting the third portion 83, and the core portion 74 (FIG. 21, part (a)). After removing portions of the insulating film 7 while leaving the bottom end portion 71 of the insulating film 7 and the core portion 74, the bottom end portion 71 is thermally oxidized to form the thermal oxide film 72 (FIG. 21, part (b)).

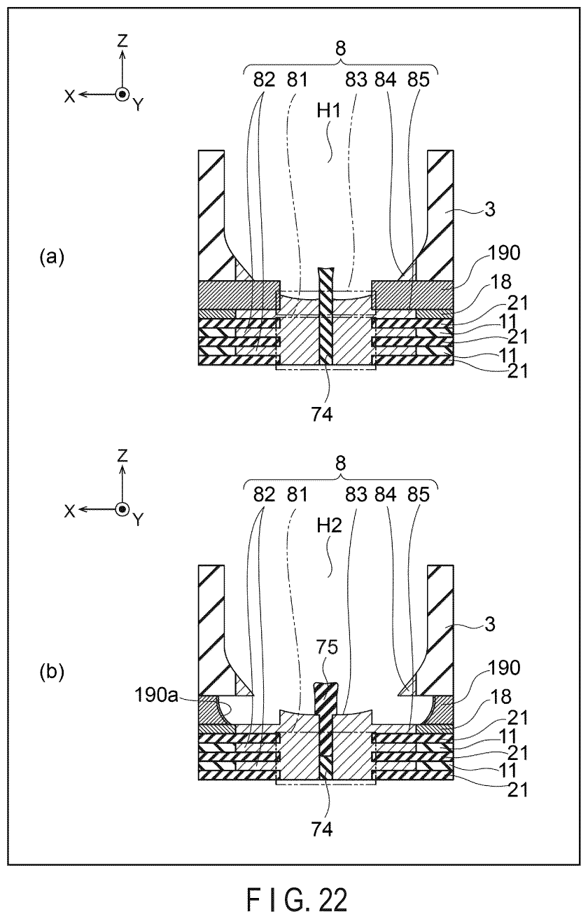

After forming the thermal oxide film 72, the third portion 83 and the fourth portion 84 are partially removed by wet etching using a chemical solution. When partially removing the third portion 83 and the fourth portion 84, the thermal oxide film 72 on the third portion 83 is entirely removed. Since the etching rate of the third portion 83 is less than the etching rate of the fourth portion 84 (due to the thermal oxide film 72), after the thermal oxide film 72 is removed by wet etching, an upper end portion of the core portion 74 remains with the upper end portion projecting upward from the insulating film 8 (FIG. 22, part (a)).

Next, the side wall 190a of the sacrificial layer 190 is recessed relative to the side walls of the sacrificial layers 21 by wet etching using a chemical solution (FIG. 22, part (b)). After recessing the side wall 190a of the sacrificial layer 190 relative to the side walls of the sacrificial layers 21, the recessed side wall 190a is oxidized. Accordingly, the concave portion H2 of the insulating film 8 is formed (FIG. 22, part (b)). After forming the concave portion H2, the insulating film 75 is formed by thermally oxidizing the upper end portion of the core portion 74 (FIG. 22, part (b)). Note that, when forming the insulating film 75 (e.g., a SiCN film) that fills the gap G (instead of forming the insulating film 74), it is unnecessary to thermally oxidize the upper end portion of the insulating film 75. Since the insulating film 75 projects upward from the insulating film 8, the center portion of the bottom surface of the concave portion H2 has a convex shape.

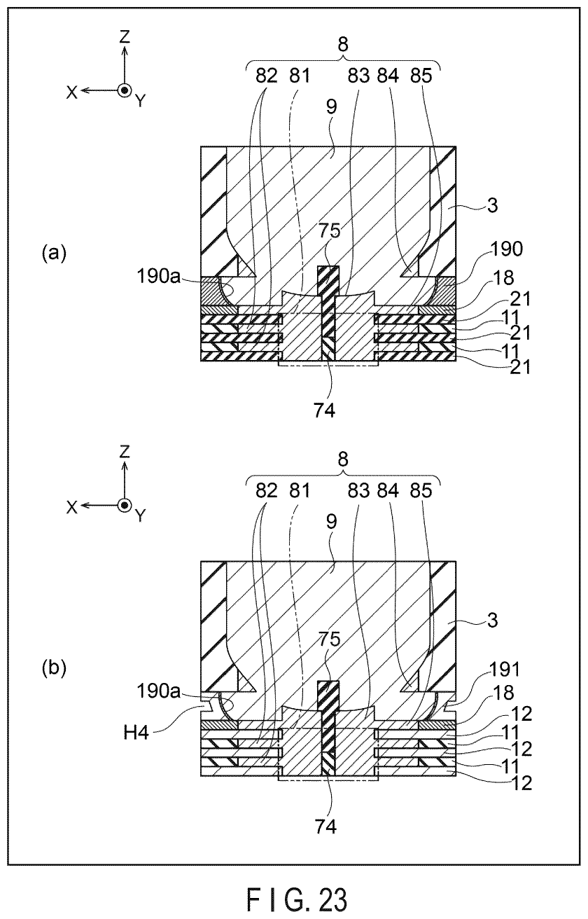

Next, the insulating film 9 is formed in the concave portion H2 (FIG. 23, part (a)).

After forming the insulating film 9, the concave portion H4 is formed by removing the sacrificial layer 190 by wet etching using a chemical solution, leaving the oxidized side wall 190a of the sacrificial layer 190 (FIG. 23, part (b)). The concave portions H3 are then formed by removing the sacrificial layers 21 by wet etching using a chemical solution (refer to FIG. 10, part (a)).

After forming the concave portions H3 and H4, the electrode layers 12 are formed in the concave portions H3, and the conductive layer 191 is formed in the concave portion H4 (FIG. 23, part (b)). The conductive layers can also be formed in the slits ST at this time. After the electrode layers 12 are formed in the concave portions H3, the sacrificial layers 21 of the lamination film 20 can be said to have been replaced with the electrode layers 12.

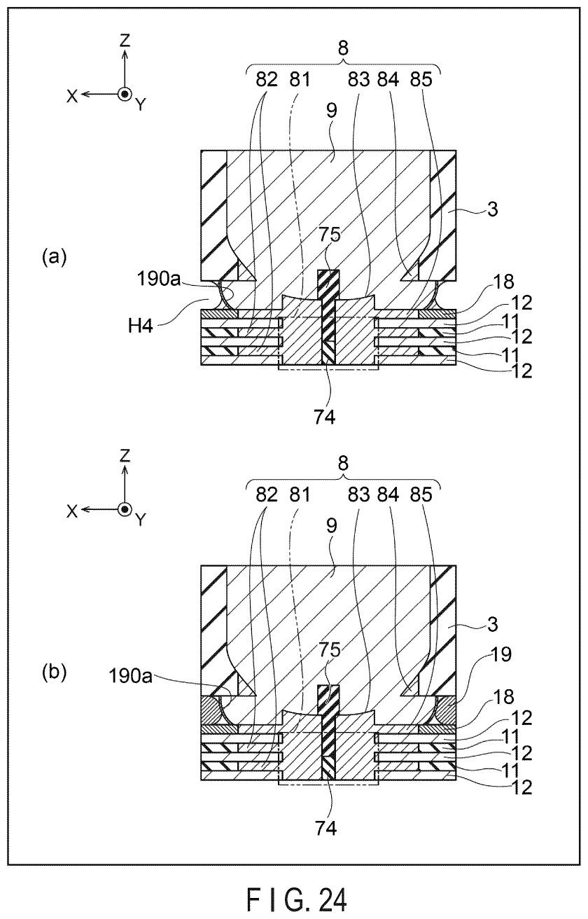

After forming the electrode layers 12 and the conductive layer 191, the conductive layer in the concave portion H4 is removed together with the conductive layers in the slits ST by wet etching using a chemical solution (FIG. 24, part (a)).

After removing the conductive layer in the concave portion H4, the insulating film 19 is formed in the concave portion H4 and the slits ST (FIG. 24, part (b)).

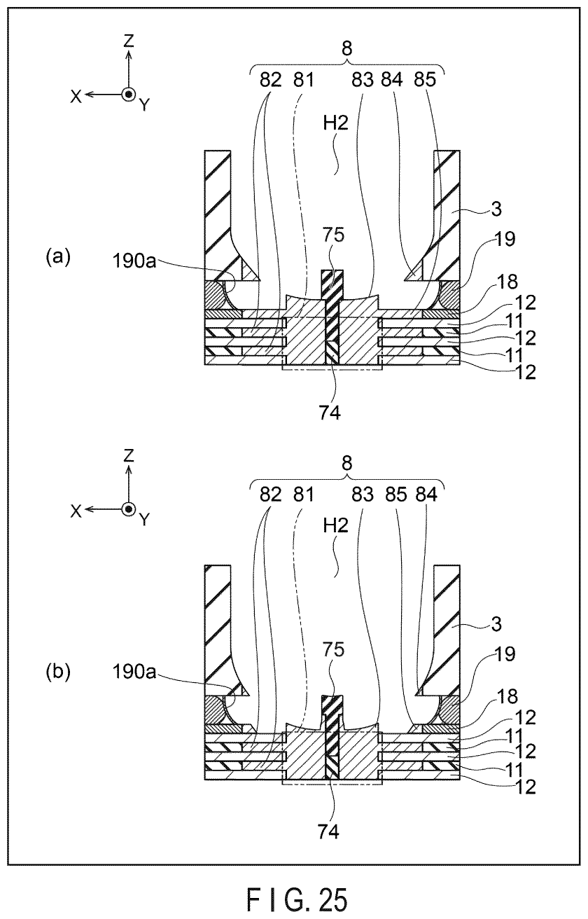

After forming the insulating film 19, the insulating film 9 in the concave portion H2 is removed by wet etching using a chemical solution (FIG. 25, part (a)). Since the material of the insulating film 75 is different from that of the insulating film 9 (amorphous silicon film) formed by the thermal oxidation of the insulating film 74 (amorphous silicon film), the removal of the insulating film 75 by the wet etching of the insulating film 9 can be reduced.

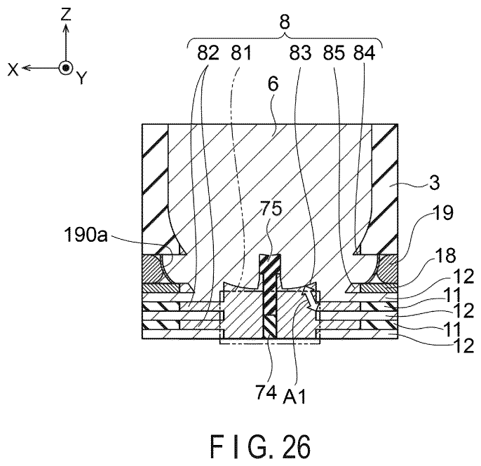

After the removing of the insulating film 9 in the concave portion H2, the uppermost electrode layer 12 can be exposed by removing most of the fifth portion 85 by etching (FIG. 25, part (b)). After exposing the uppermost electrode layer 12, the contact plug 6 is formed in the concave portion H2 (FIG. 26). Since the upper end portion of the insulating film 75 constituting the center portion of the bottom surface of the concave portion H2 has a convex shape, the center portion 6a of the lower end of the contact plug 6 will have a concave shape. Since the center portion 6a has a concave shape, the interval A1 between the lower end of the contact plug 6 and the electrode layer 12 under the uppermost electrode layer 12 can be increased. Accordingly, the voltage resistance between the contact plug 6 and a word line to which the contact plug is not intended to be connected can be improved.

As described above, in the second embodiment, the insulating film 75 located under the center portion 6a of the lower end of the contact plug 6 and protruding upward from the insulating film 8 is provided in the insulating film 8.

Accordingly, the center portion 6a of the lower end of the contact plug 6 can be formed into the concave shape by a simple method.

Additionally, in the second embodiment, the insulating film 74 provided in the insulating film 8 and located under the insulating film 75 can be further included.

Accordingly, the insulating film 75 can be simply formed by thermally oxidizing the insulating film 74.

### Third Embodiment

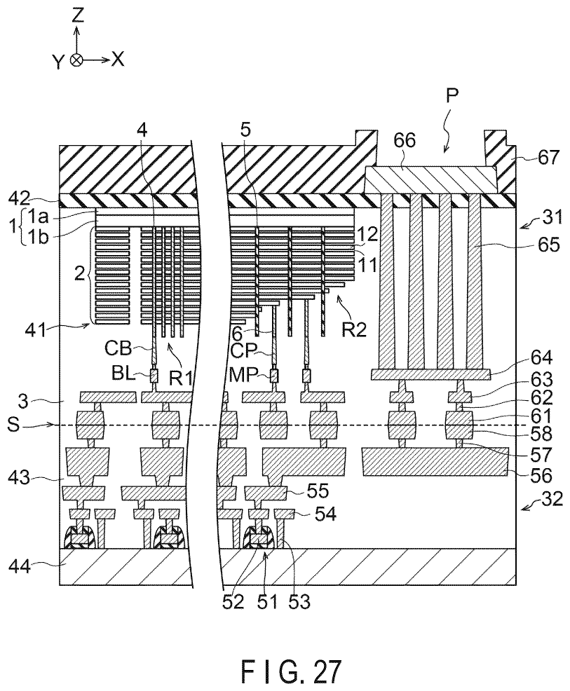

FIG. 27 is a cross-sectional view illustrating the structure of a semiconductor device according to a third embodiment. The semiconductor device according to the third embodiment corresponds to an example of the semiconductor device according to the first embodiment. The semiconductor device according to the third embodiment is a three-dimensional semiconductor memory in which an array chip 31 and a circuit chip 32 are bonded to each other.

The array chip 31 includes a memory cell array 41 including a source layer 1, a lamination film 2, pillar-shaped portions 4, beam portions 5, contact plugs 6, and the like, an insulating film 42 on the memory cell array 41, and the interlayer insulation film 3 under the memory cell array 41. The depicted orientation of the semiconductor device illustrated in FIG. 27 is opposite to the orientation of the semiconductor device illustrated in FIG. 1. Although FIG. 27 illustrates the flat portion R1 and the stair structure portion R2 in the lamination film 2, specific illustration of the insulating film 8 is omitted.

The circuit chip 32 is located under the array chip 31. A interface S is the bonding interface between the array chip 31 and the circuit chip 32. The circuit chip 32 includes interlayer insulation film 43 and a substrate 44 under the interlayer insulation film 43. The substrate 44 is, for example, a semiconductor substrate such as a silicon substrate. In FIG. 27, a surface of the substrate 44 is parallel to the X direction and the Y direction, and is perpendicular to the Z direction.

The array chip 31 includes, as a plurality of electrode layers in the memory cell array 41, the source layer 1 that functions as a source line, and the plurality of electrode layers 12 that function as word lines or selection lines. These electrode layers 12 are alternately laminated with the plurality of insulating films 11. Each pillar-shaped portion 4 is electrically connected to the bit line BL via a contact plug CB, and is electrically connected to the source layer 1. The source layer 1 includes a metal layer 1a and a semiconductor layer 1b. Each contact plug 6 is electrically connected to a wiring MP via a contact plug CP.

The circuit chip 32 includes a plurality of transistors 51. Each transistor 51 includes a gate electrode 52 provided on the substrate 44 via a gate insulating film along with a source diffusion layer and a drain diffusion layer provided in the substrate 44. Additionally, the circuit chip 32 includes a plurality of contact plugs 53 provided on the gate electrodes 52, the source diffusion layers, or the drain diffusion layers of these transistors 51, a wiring layer 54 provided on these contact plugs 53 and including a plurality of wirings, and a wiring layer 55 provided on the wiring layer 54 and including a plurality of wirings.

The circuit chip 32 further includes a wiring layer 56 provided on the wiring layer 55 and including a plurality of wirings, a plurality of via plugs 57 provided on the wiring layer 56, and a plurality of metal pads 58 provided on these via plugs 57. The metal pad 58 is, for example, a metal layer including a Cu layer. The circuit chip 32 functions as a logic circuit (CMOS circuit) that controls the operation of the array chip 31. This logic circuit is constituted by the transistors 51 and the like, and is electrically connected to the metal pads 58.

The array chip 31 includes a plurality of metal pads 61 provided on the metal pads 58, and a plurality of via plugs 62 provided on the metal pads 61. Additionally, the array chip 31 includes a wiring layer 63 provided on these via plugs 62 and including a plurality of wirings, and a wiring layer 64 provided on the wiring layer 63 and including a plurality of wirings. The metal pad 61 is, for example, a metal layer including a Cu layer. The above-described bit line BL and wiring MP are included in the wiring layer 64. The above-described logic circuit is electrically connected to the memory cell array 41 via the metal pads 58 and 61 and the like, and controls the operation of the memory cell array 41 via the metal pads 58 and 61 and the like. This logic circuit includes, for example, the transistors 51 electrically connected to the bit line BL via the metal pads 58 and 61 and the like, and the transistors 51 electrically connected to the wiring MP via the metal pads 58 and 61 and the like.

The array chip 31 further includes a plurality of via plugs 65 provided on the wiring layer 64, a metal pad 66 provided on these via plugs 65 and the insulating film 42, and a passivation film 67 provided on the metal pad 66 and the insulating film 42. The metal pad 66 is, for example, a metal layer including a Cu layer, and functions as an external connection pad (bonding pad) of the semiconductor device in FIG. 27. The passivation film 67 is, for example, an insulating film such as a silicon oxide film, and has an opening P that exposes an upper surface of the metal pad 66. The metal pad 66 is connectable to a mounting substrate or other devices by a bonding wire, a solder ball, a metal bump, or the like via this opening P.

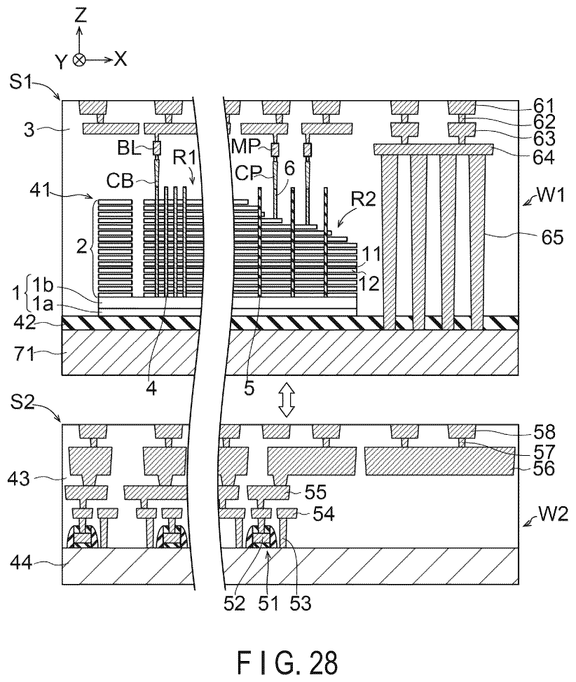

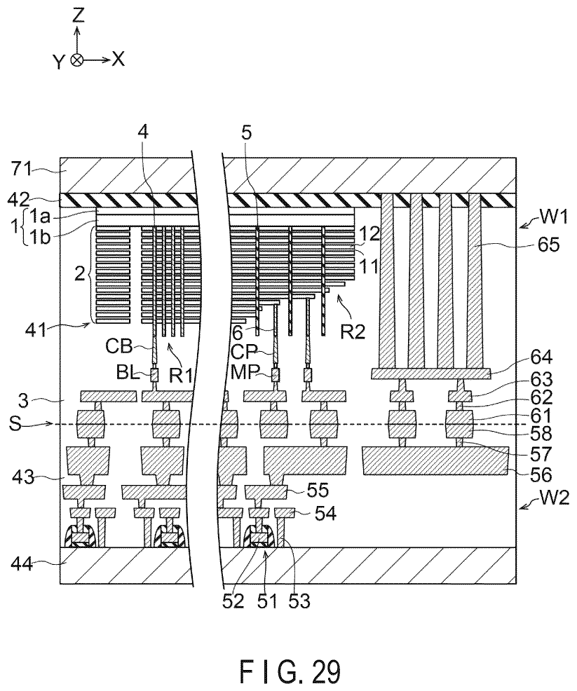

FIG. 28 and FIG. 29 are cross-sectional views illustrating aspects of a manufacturing method of the semiconductor device according to the third embodiment.

FIG. 28 illustrates an array wafer W1 including a plurality of array chips 31, and a circuit wafer W2 including a plurality of circuit chips 32. The orientation of the array wafer W1 illustrated in FIG. 28 is opposite to the orientation of the array chip 31 illustrated in FIG. 27. In the third embodiment, the semiconductor device is manufactured by bonding the array wafer W1 and the circuit wafer W2 together. FIG. 28 illustrates the array wafer W1 before the orientation is reversed for bonding, and FIG. 27 illustrates the array chip 31 after the orientation is reversed for bonding, and bonding and dicing are performed.

In FIG. 28, a surface S1 is an upper surface of the array wafer W1, and a surface S2 is an upper surface of the circuit wafer W2. The array wafer W1 includes a substrate 71 provided under the insulating film 42. The substrate 71 is, for example, a semiconductor substrate such as a silicon substrate.

In the third embodiment, as illustrated in FIG. 28, the memory cell array 41, the insulating film 42, the source layer 1, the lamination film 2, the interlayer insulation film 3, the pillar-shaped portions 4, the beam portions 5, the contact plugs 6, the metal pads 61, and the like are formed on the substrate 71 of the array wafer W1, and the interlayer insulation film 43, the transistors 51, the metal pads 58, and the like are formed on the substrate 44 of the circuit wafer W2. Next, as illustrated in FIG. 29, the array wafer W1 and the circuit wafer W2 are brought together by mechanical pressure. Accordingly, the interlayer insulation film 3 and the interlayer insulation film 43 are bonded to each other. Next, the array wafer W1 and the circuit wafer W2 are annealed. Accordingly, the metal pads 58 and the metal pads 61 are joined to one another.

Then, after reducing the thickness of the substrate 44 by chemical mechanical polishing (CMP), and removing the substrate 71 by CMP, the array wafer W1 and the circuit wafer W2 are cut (diced) into a plurality of individual chips. In this manner, the semiconductor device illustrated in FIG. 27 is manufactured. Note that the metal pad 66 and the passivation film 67 can be formed on the insulating film 42 after, for example, the reduction of the thickness of the substrate 44 and the removal of the substrate 71.

Note that, although FIG. 27 illustrates a recognizable border between the interlayer insulation film 3 and the interlayer insulation film 43, and a recognizable border between the metal pads 58 and the metal pads 61, the interface between these elements may not be readily observed after the above-described annealing. However, the positions at which these borders were present may sometimes be estimated by detecting, for example, the inclination of the side surfaces of the metal pads 58 and the side surfaces of the metal pads 61, or a position shift between the side surfaces of the metal pads 58 and the metal pads 61.

According to the third embodiment, it becomes possible to apply the structure described in the first embodiment to a semiconductor device in which the array chip 31 and the circuit chip 32 are joined to each other. Note that, although the array chip 31 and the circuit chip 32 are joined to each other in the third embodiment, in other examples, array chips 31 may be joined to each other instead. Additionally, the third embodiment may be applied to the second embodiment.

While certain embodiments have been described, these embodiments have been presented by way of example only, and are not intended to limit the scope of the inventions. Indeed, the novel devices and methods described herein may be embodied in a variety of forms; other furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first lamination film including a plurality of first insulating films and a plurality of electrode layers alternately laminated in a first direction;
a plurality of contact plugs extending in the first direction, wherein
each electrode layer in the first lamination film contacts a contact plug in the plurality of contact plugs in a stair step region of the first lamination film,
each contact plug contacts an uppermost electrode layer of the plurality of electrode layers in a stair step of the stair step region, and
a center portion of a lower end of each contact plug has a concave shape.

2. The semiconductor device of claim 1, further comprising:
a second insulating film on the first lamination film, wherein
the contact plugs penetrate the second insulating film, and
a thickness of the second insulating film in the first direction is greater than a thickness of an individual first insulating film in the first direction.

3. The semiconductor device of claim 2, further comprising:
a third insulating film between the second insulating film and the first lamination film, wherein
the third insulating film has a thickness in the first direction that is less than the thickness of the second insulating film in the first direction.

4. The semiconductor device of claim 3, wherein the first insulating film, the second insulating film, and the third insulating film comprise silicon and oxygen.

5. The semiconductor device of claim 1, further comprising:
a fourth insulating film penetrating the first lamination film in the first direction and located under a contact plug in the first direction.

6. The semiconductor device of claim 5, wherein a center portion of an upper end of the fourth insulating film has a convex shape corresponding to the concave shape of the center portion of the lower end of a corresponding contact plug.

7. The semiconductor device of claim 6, wherein the fourth insulating film includes:
a first portion penetrating the first lamination film, and
a plurality of second portions located on an outer side of the first portion and adjacent to side walls of the plurality of first insulating films.

8. The semiconductor device of claim 5, further comprising:
a fifth insulating film in the fourth insulating film and extending in the first direction, wherein
an upper end portion of the fifth insulating film has a convex shape corresponding to the concave shape of the corresponding contact plug.

9. The semiconductor device of claim 8, further comprising:
a sixth insulating film in the fourth insulating film and extending in the first direction, wherein
the sixth insulating film is under the fifth insulating film.

10. The semiconductor device of claim 9, wherein the sixth insulating film is amorphous silicon.

11. The semiconductor device of claim 8, wherein
the fourth insulating film comprises silicon and oxygen, and
the fifth insulating film comprises silicon and oxygen or silicon, carbon, and nitrogen.

12. The semiconductor device of claim 1, wherein the first lamination film includes a flat region adjacent to the stair step region.

13. A manufacturing method of a semiconductor device, the manufacturing method comprising:
forming a lamination film including a plurality of first insulating films and a plurality of first sacrificial films alternately in a first direction;
forming a second insulating film on the lamination film;
forming a first concave portion penetrating the second insulating film and the lamination film;
recessing a side wall of the second insulating film and side walls of the plurality of first insulating films relative to a side wall of the first sacrificial films in the first concave portion;
forming, in the first concave portion, a third insulating film including:
a first portion penetrating the lamination film,
a plurality of second portions located on an outer side of the first portion and adjacent to the side walls of the plurality of first insulating films,
a third portion located on the first portion, and
a fourth portion located above the second portion;
processing the third insulating film such that an etching of a center portion of the third portion is less than an etching of the fourth portion;
removing at least a part of the third portion and the fourth portion by etching to form a second concave portion in the third insulating film, a center portion of a bottom surface of the second concave portion having a convex shape; and
forming, in the second concave portion, a first conductive plug extending in the first direction.

14. The manufacturing method of claim 13, further comprising:
removing first sacrificial films to form a plurality of third concave portions in the lamination film; and
forming a plurality of electrode layers in the plurality of third concave portions.

15. The manufacturing method of claim 13, further comprising:
forming, on the lamination film, a second sacrificial film having a thickness in the first direction greater than an individual first insulating film, wherein
the first concave portion penetrates the second sacrificial film.

16. The manufacturing method of claim 15, wherein
the second sacrificial film is formed on the lamination film on a fourth insulating film,
the fourth insulating film has a thickness in the first direction that is less than the second sacrificial film, and
the first concave portion penetrates the fourth insulating film.

17. The manufacturing method of claim 14, wherein processing of the third insulating film includes:
forming a fifth insulating film on the third portion and the fourth portion;
removing portions of the fifth insulating film but leaving a bottom end portion of the fifth insulating film contacting the third portion; and
thermally oxidizing the bottom end portion of the fifth insulating film, and
formation of the second concave portion includes removing the thermally oxidized bottom end portion of the fifth insulating film when removing at least portions of the third portion and the fourth portion.

18. The manufacturing method of claim 17, wherein
the third insulating film is formed in the first concave portion so as to leave a gap in a center portion of the first portion and the center portion of the third portion,
the fifth insulating film is formed to have a core portion that fills the gap,
the second concave portion is formed such that an upper end portion of the core portion protrudes upward from the third insulating film after the thermally oxidized bottom end portion of the fifth insulating film is removed, and
the manufacturing method further comprises:
forming a sixth insulating film by thermally oxidizing the upper end portion of the core portion before forming the first conductive plug in the second concave portion.

19. The manufacturing method of claim 14, wherein
the third insulating film is formed so as to leave a gap in a center portion of the first portion and the center portion of the third portion,
processing of the third insulating film includes forming a sixth insulating film filling the gap, and
the second concave portion is formed such that the sixth insulating film protrudes from the third insulating film when the third portion and the fourth portion are being at least partially removed.

20. The manufacturing method of claim 17, further comprising:
forming, on the lamination film, a second sacrificial film having a thickness in the first direction greater than the individual first insulating films and the first sacrificial films, wherein
the first concave portion penetrates the second sacrificial film,
formation of the second concave portion further includes:
recessing a side wall of the second sacrificial film relative to a side wall of a first sacrificial film after at least partially removing the third portion and the fourth portion; and
oxidizing the recessed side wall of the second sacrificial film,
the manufacturing method further comprising:
forming a seventh insulating film in the second concave portion after oxidizing the side wall of the second sacrificial film;
forming a fourth concave portion by removing the second sacrificial film but leaving the oxidized side wall after the seventh insulating film is formed;
forming an eighth insulating film in the fourth concave portion; and
removing the seventh insulating film after forming the eighth insulating film, and
the first conductive plug is formed in the second concave portion after the seventh insulating film is removed.
